(19) United States
(12) Patent Application Publication
(10) Pub. No.: US 2021/0082949 A1
(43) Pub. Date: Mar. 18, 2021

(54) SEMICONDUCTOR MEMORY DEVICE AND METHOD FOR MANUFACTURING SEMICONDUCTOR MEMORY DEVICE

(71) Applicant: Kioxia Corporation, Minato-ku (JP)

(72) Inventors: Hisashi HARADA, Yokkaichi (JP); Ayaha HACHISUGA, Yokkaichi (JP); Jun NISHIMURA, Kuwana (JP); Wataru UNNO, Kuwana (JP)

(73) Assignee: Kioxia Corporation, Minato-ku (JP)

(21) Appl. No.: 16/816,385

(22) Filed: Mar. 12, 2020

(30) Foreign Application Priority Data
Sep. 17, 2019 (JP) 2019-168051

(51) Int. Cl. H01L 27/11582; H01L 21/768

(52) U.S. Cl. CPC H01L 27/11582; H01L 21/76898; H01L 21/76804

(57) ABSTRACT

According to one embodiment, a semiconductor memory device includes a first stacked body disposed between the belt-like portions and stacked a plurality of first conductive layers via a first insulating layer, a second stacked body disposed in a region in the first stacked body and stacked a plurality of second insulating layers via the first insulating layer, a first pillar extending in the first stacked body in a stacking direction of the first stacked body, and a plurality of second pillars extending in the stacking direction on both sides of the second stacked body facing the belt-like portions and arranged in the first direction, in which the second pillars each include a plate-like portion disposed at a height position of each of the first conductive layers, and the adjacent second pillars are connected to each other by the plate-like portion.

### CROSS-REFERENCE TO RELATED APPLICATIONS

This application is based upon and claims the benefit of priority from Japanese Patent Application No. 2019-168051, filed on Sep. 17, 2019; the entire contents of which are incorporated herein by reference.

### FIELD

Embodiments described herein relate generally to a semiconductor memory device and a method for manufacturing the semiconductor memory device.

### BACKGROUND

In a process for manufacturing a three-dimensional nonvolatile memory, a stacked body of conductive layers is formed by, for example, replacing a plurality of insulating layers with the conductive layers. For example, in order to pass a contact connecting the upper and lower structures of the stacked body, a part of the stacked body can be maintained as insulating layers without being replaced with conductive layers. At this time, it is desired to more easily inhibit the replacement with the conductive layers.

### BRIEF DESCRIPTION OF THE DRAWINGS

FIG. 1 is a cross-sectional view illustrating a schematic configuration example of a semiconductor memory device according to an embodiment;

FIGS. 2A to 2C are cross-sectional views illustrating a detailed configuration example of the semiconductor memory device according to the embodiment;

FIG. 3 is a latitudinal cross-sectional view of the semiconductor memory device according to the embodiment;

FIGS. 4A and 4B are enlarged sectional views of pillars of the semiconductor memory device according to the embodiment;

FIGS. 5A to 5C are cross-sectional views illustrating an example of a procedure in a method for manufacturing the semiconductor memory device according to the embodiment;

FIGS. 6A to 60 are cross-sectional views illustrating an example of the procedure in the method for manufacturing the semiconductor memory device according to the embodiment;

FIGS. 7A to 7C are cross-sectional views illustrating an example of the procedure in the method for manufacturing the semiconductor memory device according to the embodiment;

FIGS. 8A to 8C are cross-sectional views illustrating an example of the procedure in the method for manufacturing the semiconductor memory device according to the embodiment;

FIGS. 9A to 9C are cross-sectional views illustrating an example of the procedure in the method for manufacturing the semiconductor memory device according to the embodiment;

FIGS. 10A to 100 are cross-sectional views illustrating an example of the procedure in the method for manufacturing the semiconductor memory device according to the embodiment;

FIGS. 11A to 11C are cross-sectional views illustrating an example of the procedure in the method for manufacturing the semiconductor memory device according to the embodiment;

FIGS. 12A to 12C are cross-sectional views illustrating an example of the procedure in the method for manufacturing the semiconductor memory device according to the embodiment;

FIGS. 13A to 13C are cross-sectional views illustrating an example of the procedure in the method for manufacturing the semiconductor memory device according to the embodiment;

FIGS. 14A to 14C are cross-sectional views illustrating an example of the procedure in the method for manufacturing the semiconductor memory device according to the embodiment;

FIGS. 15A to 15C are cross-sectional views illustrating an example of the procedure in the method for manufacturing the semiconductor memory device according to the embodiment;

FIGS. 16A to 16C are cross-sectional views illustrating an example of the procedure in the method for manufacturing the semiconductor memory device according to the embodiment;

FIGS. 17A to 17C are cross-sectional views illustrating an example of the procedure in the method for manufacturing the semiconductor memory device according to the embodiment;

FIGS. 18A to 18C are cross-sectional views illustrating an example of the procedure in the method for manufacturing the semiconductor memory device according to the embodiment;

FIGS. 19A to 19C are cross-sectional views illustrating an example of the procedure in the method for manufacturing the semiconductor memory device according to the embodiment;

FIGS. 20A to 20C are cross-sectional views illustrating an example of the procedure in the method for manufacturing the semiconductor memory device according to the embodiment;

FIG. 21 is a latitudinal cross-sectional view of the semiconductor memory device according to Modified example 1 of the embodiment; and

FIGS. 22A to 22C are cross-sectional views illustrating a detailed configuration example of the semiconductor memory device according to Modified example 2 of the embodiment.

### DETAILED DESCRIPTION

In general, according to one embodiment, a semiconductor memory device includes a substrate, a plurality of belt-like portions arranged abreast to each other above the substrate and extending in a first direction along the substrate, a first stacked body disposed between the belt-like portions and stacked a plurality of first conductive layers via a first insulating layer, a second stacked body disposed in a region in the first stacked body and stacked a plurality of second insulating layers via the first insulating layer, a first pillar extending in the first stacked body in a stacking direction of the first stacked body and forming a memory cell at an intersection with at least a part of the first conductive layers, and a plurality of second pillars extending in the stacking direction on both sides of the second stacked body facing the belt-like portions and arranged in the first direction, in which the second pillars each include a plate-like portion disposed at a height position of each of the first conductive layers, and the adjacent second pillars are connected to each other by the plate-like portion.

Exemplary embodiments of a semiconductor memory device and a method for manufacturing the semiconductor memory device will be explained below in detail with reference to the accompanying drawings. The present invention is not limited to the following embodiments. In addition, constituent elements in the following embodiments include those that can be easily conceived by those skilled in the art or that are substantially the same.

(Configuration Example of Semiconductor Memory Device)

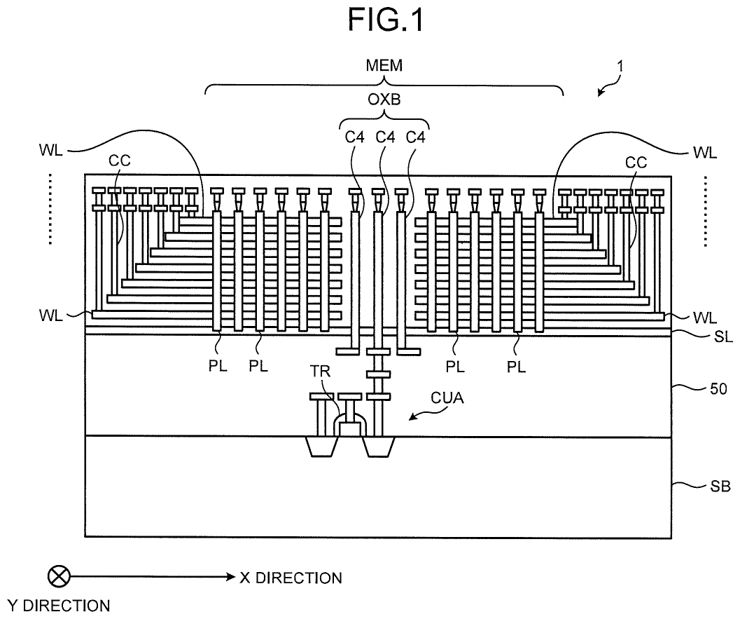

FIG. 1 is a cross-sectional view illustrating a schematic configuration example of a semiconductor memory device 1 according to an embodiment. As illustrated in FIG. 1, the semiconductor memory device 1 includes a substrate SB, a peripheral circuit CUA, and a memory portion MEM as a memory region.

The substrate SB is, for example, a semiconductor substrate, such as a silicon substrate. On the substrate SB, the peripheral circuit CUA including a transistor TR and wiring is disposed.

The peripheral circuit CUA contributes to the operation of a memory cell to be described later. The peripheral circuit CUA is covered with an insulating layer 50. On the insulating layer 50, a source line SL is disposed. On the source line SL, a plurality of word lines WL is stacked.

In the word lines WL, a plurality of pillars PL penetrating the word lines WL in the stacking direction is disposed. At the intersections of the pillars PL and the word lines WL, a plurality of memory cells is formed. As a result, the memory portion MEM is configured by three-dimensionally disposing the memory cells.

In the memory portion MEM, a through contact region OXB including no word line WL is disposed. In the through contact region OXB, contacts C4 that connect the peripheral circuit CUA below the memory portion MEM to upper layer wiring and the like above the memory portion MEM are disposed.

The ends of the word lines WL are formed in a step shape. At the end of each word line WL, a contact CC that connects the word line WL to the upper layer wiring and the like is disposed. As a result, the word lines WL stacked in multiple layers can be led out individually.

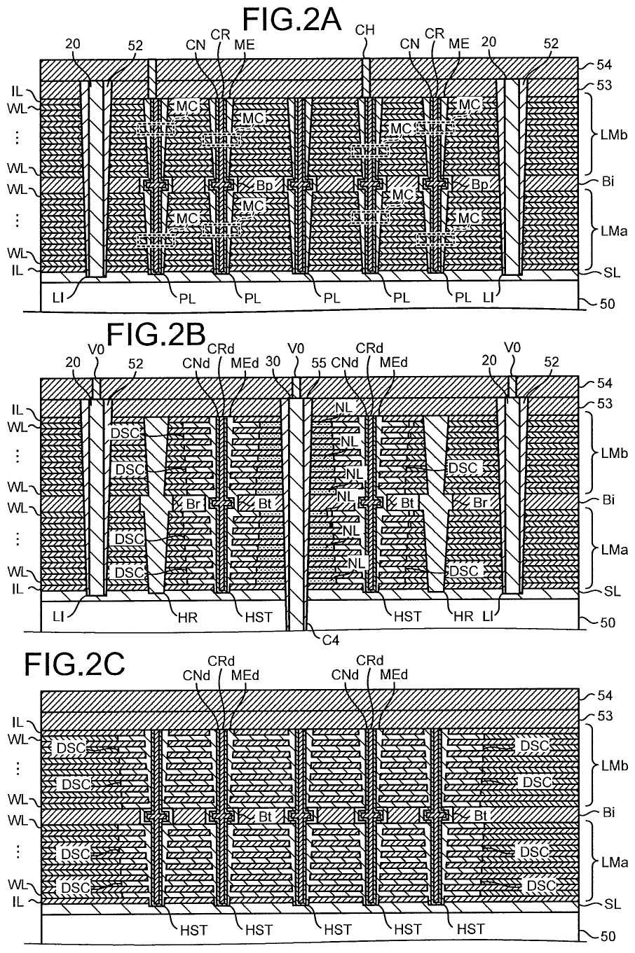

Next, a detailed configuration example of the semiconductor memory device 1 is described with reference to FIGS. 2A to 4B.

FIGS. 2A to 2C are cross-sectional views illustrating a detailed configuration example of the semiconductor memory device 1 according to the embodiment. FIG. 2A is a cross-sectional view of the memory portion MEM of the semiconductor memory device 1 in the Y direction. FIG. 2B is a cross-sectional view of the memory portion MEM including the through contact region OXB of the semiconductor memory device 1 in the Y direction. FIG. 2C is a cross-sectional view of a replacement inhibition portion INr of the semiconductor memory device 1 in the X direction. In FIGS. 2A to 2C, the configuration below the insulating layer 50 is omitted.

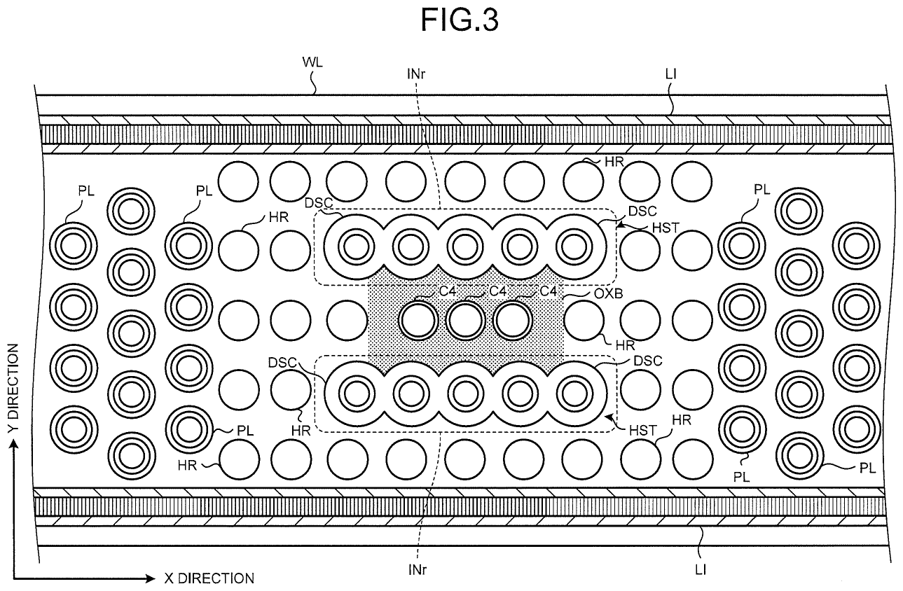

FIG. 3 is a latitudinal cross-sectional view of the semiconductor memory device 1 according to the embodiment. FIG. 3 illustrates the memory portion MEM including the through contact region OXB, and is a cross-sectional view at the position of a predetermined word line WL in the direction along the substrate SB.

As illustrated in FIG. 2A, the source line SL is disposed on the insulating layer 50. The source line SL is, for example, a polysilicon layer.

On the source line SL, a stacked body LMa, in which word lines WL as conductive layers and insulating layers IL are alternately stacked in multiple layers, is disposed. On the stacked body LMa, a stacked body LMb, in which word lines WL as conductive layers and insulating layers IL are alternately stacked in multiple layers, is disposed via a bonding layer Bi. Each word line WL is, for example, a tungsten layer, a molybdenum layer, or the like. Each insulating layer IL and the bonding layer Bi are, for example, SiO₂ layers or the like.

In the example of FIG. 2A, the stacked bodies LMa and LMb as a first stacked body each include seven word lines WL, but the number of word lines WL is arbitrary. The stacked body LMa may be configured by disposing a selection gate line (not illustrated) below the lowermost word line WL, and the stacked body LMb may be configured by disposing a selection gate line (not illustrated) above the uppermost word line WL.

On the source line SL, a plurality of contacts LI is disposed. Each contact LI penetrates an insulating layer 53 on the stacked body LMb and the stacked bodies LMa and LMb, and reaches the source line SL. By disposing the contacts LI each including a conductive layer 20 on the source line SL in this manner, the contacts LI function as, for example, source line contacts. The contacts LI are each configured in a belt-like shape extending in the X direction, and divide the stacked bodies LMa and LMb in the Y direction.

Each contact LI has an insulating layer 52 covering the sidewall of the divided stacked bodies LMa and LMb. The inside the insulating layer 52 of each contact LI is further filled with the conductive layer 20. The insulating layer 52 is, for example, a SiO₂ layer or the like. The conductive layer 20 is, for example, a polysilicon layer, a tungsten layer, or the like. Note that, the stacked bodies LMa and LMb may be divided in the Y direction by belt-like insulating layers constituted only by, for example, SiO₂ layers, instead of the contacts LI.

In the stacked bodies LMa and LMb between the two contacts LI, a plurality of pillars PL as first pillars is disposed. Each pillar PL penetrates the stacked bodies LMa and LMb and the bonding layer Bi and reaches the source line SL. Each pillar PL includes a bonding portion Bp in the bonding layer Bi.

Each pillar PL includes a memory layer ME, a channel layer CN, and a core layer CR in this order from the outer peripheral side of the pillar PL. The channel layer CN is also disposed at the bottom of the pillar PL, and the channel layer CN is connected to the source line SL at the lower end of the pillar PL. The memory layer ME is a stacked layer of, for example, a SiO₂ layer/SiN layer/SiO₂ layer, the channel layer CN is, for example, an amorphous silicon layer, a polysilicon layer, or the like, and the core layer CR is, for example, an SiO₂ layer or the like.

On the stacked body LMb, the insulating layer 53 is disposed. On the insulating layer 53, an insulating layer 54 is disposed. The channel layer CN of each pillar PL is connected to upper layer wiring, such as a bit line or the like, by a plug CH penetrating the insulating layers 53 and 54. The conductive layer 20 of each contact LI is connected to the upper wiring by a plug VO penetrating the insulating layer 54.

With the above configuration, at respective intersections of the pillars PL and the word lines WL, a plurality of memory cells MC is formed. By applying a predetermined voltage from the word lines WL, accumulating charges in the memory cells MC, and the like, data is written in the memory cells MC. By applying a predetermined voltage from the word lines WL, data written in the memory cells MC is read.

As described above, the semiconductor memory device 1 is configured as a three-dimensional nonvolatile memory in which, for example, the memory cells MC are three-dimensionally disposed.

As illustrated in FIGS. 2B and 3, a plurality of columnar portions HR is disposed in a grid in the vicinity of the through contact region OXB. Each columnar portion HR penetrates the stacked bodies LMa and LMb and the bonding layer Bi and reaches the source line SL. Each columnar portion HR includes a bonding portion Br in the bonding layer Bi. Each columnar portion HR is filled with an insulating layer, such as a SiO₂ layer or the like. The columnar portions HR each have a lower end connected to the source line SL, and support the stacked bodies LMa and LMb in a process for replacing insulating layers NL with the word lines WL, which will be described later.

The through contact region OXB as a second stacked body does not include word lines WL at the positions corresponding to the word lines WL of the stacked bodies LMa and LMb. Instead, the insulating layers NL, such as SiN layers or the like, are disposed, in the through contact region OXB, at the height positions corresponding to the word lines WL. That is, the through contact region OXB is configured by alternately stacking the insulating layers NL and the insulating layers IL in multiple layers.

For example, a plurality of contacts C4 are disposed in the through contact region OXB. Each contact C4 penetrates the insulating layer 53 above the through contact region OXB, the through contact region OXB, and the source line SL, and has a lower end connected to lower layer wiring and the like constituting the peripheral circuit CUA. Each contact C4 includes an insulating layer 55 on the outer peripheral side of the contact C4. The inside the insulating layer 55 of each contact C4 is filled with a conductive layer 30. The insulating layer 55 is, for example, a SiO₂ layer or the like. The conductive layer 30 is, for example, a tungsten layer or the like. For example, the conductive layer 30 is connected to the upper layer wiring and the like through a plug VO penetrating the insulating layer 54.

On each side of the through contact region OXB in the Y direction, a replacement inhibition portion INr is disposed. The replacement inhibition portion INr includes a plurality of pillars HST as second pillars arranged in the X direction. Each pillar HST penetrates the boundary between the stacked bodies LMa and LMb and the through contact region OXB in the stacking direction of the stacked bodies LMa and LMb and reaches the source line SL. Each pillar HST includes a bonding portion Bt in the bonding layer Bi.

Each pillar HST includes dummy layers MEd, CNd, and CRd in this order from the outer peripheral side of the pillar HST. The dummy layer CNd is also disposed at the bottom of the pillar HST. The dummy layer MEd may be disposed at the bottom of the pillar HST. The dummy layer MEd is made of the same material as, for example, the memory layer ME. The dummy layer CNd is made of the same material as, for example, the channel layer CN. The dummy layer CRd is made of the same material as, for example, the core layer CR. Each pillar HST has a lower end connected to the source line SL similarly to each pillar PL and each columnar portion HR.

The diameter and pitch of the pillars HST at the height position of each insulating layer IL are substantially equal to the diameter and pitch of the pillars PL described above, for example.

A plurality of flat plate-like portions DSC protrudes from the side surface of each pillar HST at the height positions of the word lines WL. Each plate-like portion DSC has a shape formed by, for example, overlapping the end portion of a disk-like member extending concentrically with the side surface of each pillar HST with the end portions of the adjacent pillars HST in a top view.

As a result, the adjacent pillars HST are connected to each other by the end portions of the plate-like portions DSC at the same height position. In addition, the insulating layers IL are continuously disposed in the through contact region OXB and the stacked bodies LMa and LMb on both sides of the through contact region OXB through the adjacent pillars HST. In contrast, as to be described later, the word lines WL the replacement of which from the insulating layers NL is inhibited in the replacement inhibition portion INr each has an edge facing the pillars HST connected by the plate-like portion DSC and having a shape formed by connecting a plurality of arcs.

As long as the adjacent pillars HST are connected to each other, the degree of overlapping of the disk-like end portions is not limited to the example of FIG. 3 and may be larger or smaller than the example of FIG. 3.

Each plate-like portion DSC is constituted by a part of the SiO₂ layer/SiN layer/SiO₂ layer constituting the dummy layer MEd. Specifically, each plate-like portion DSC is constituted by the SiO₂ layer of the dummy layer MEd that is the closest layer to the side surface of each pillar HST.

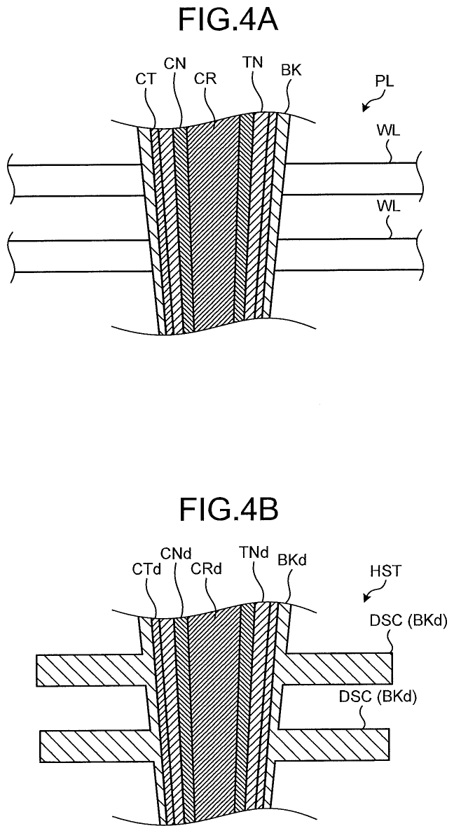

FIGS. 4A and 4B are enlarged cross-sectional views of the pillars PL and HST of the semiconductor memory device 1 according to the embodiment.

As illustrated in FIG. 4A, each pillar PL includes, as the memory layer ME, a block insulating layer BK, such as a SiO₂ layer or the like, a charge storage layer CT, such as a SiN layer or the like, and a tunnel insulating layer TN, such as a SiO₂ layer or the like, in this order from the outer peripheral side of the pillar PL.

As illustrated in FIG. 4B, each pillar HST includes, as the dummy layer MEd, a dummy layer BKd made of the same material as the block insulating layer BK, a dummy layer CTd made of the same material as the charge storage layer CT, and a dummy layer TNd made of the same material as the tunnel insulating layer TN in this order from the outer peripheral side of the pillar HST. Of these dummy layers BKd, CTd, and TNd, the plate-like portions DSC are formed from the dummy layer BKd, for example.

In the above configuration, by the pillars HST arranged in the X direction and the plate-like portions DSC protruding from the pillars HST and arranged in the height direction, the through contact region OXB is shielded from the region where the contacts LI are arranged. The pillars HST connected by the plate-like portions DSC inhibit replacement in the through contact region OXB in a process for replacing the insulating layers NL with the word lines WL, which is to be described later.

(Method for Manufacturing Semiconductor Memory Device)

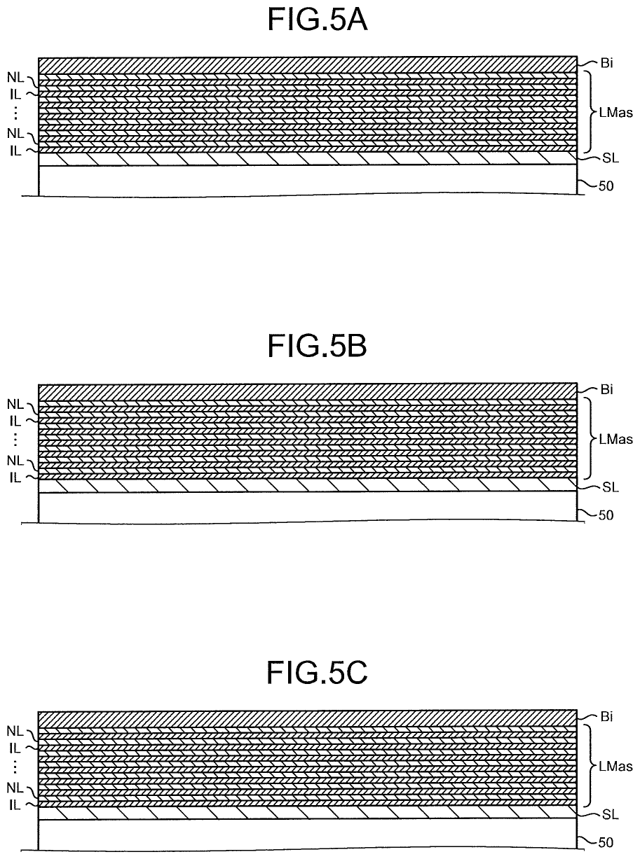

Next, an example of a method for manufacturing the semiconductor memory device 1 according to the embodiment is described with reference to FIGS. 5A to 20C.

FIGS. 5A to 20C are cross-sectional views illustrating an example of a procedure of the method for manufacturing the semiconductor memory device 1 according to the embodiment. Note that, A, B, and C in the same drawing indicate different parts in the same processing step. In addition, A in FIGS. 5A to 20C corresponds to the part in FIG. 2A, B corresponds to the part in FIGS. 2B, and C corresponds to the part in FIG. 2C.

Note that, it is assumed that the peripheral circuit CUA on the substrate SB has been formed at the time of FIG. 5A. The peripheral circuit CUA has been formed to have contacts, wirings, and the like extending to the vicinity of the surface layer of the insulating layer 50. These configurations are omitted in FIGS. 5A to 20C.

As illustrated in FIGS. 5A to 5C, after the source line SL is formed on the insulating layer 50, a stacked body LMas, in which insulating layers NL and insulating layers IL are alternately stacked in multiple layers, is formed on the source line SL. The insulating layers NL are made of, for example, SiN layers or the like and are sacrificial layers that are replaced with a conductive material later to be the word lines WL. The bonding layer Bi is formed on the stacked body LMas.

Although not illustrated in FIGS. 5A to 5C, a step-like structure is formed at each end of the stacked body LMas at this timing.

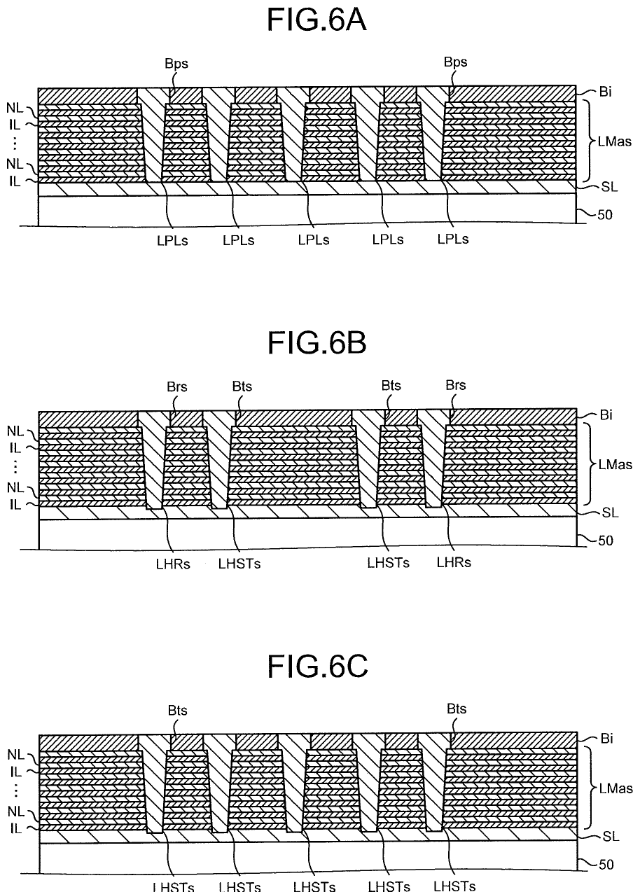

As illustrated in FIG. 6A, pillar LPLs, in which the lower layer structures of the pillars PL are each filled with a sacrificial layer, are formed in the stacked body LMas. That is, memory holes penetrating the stacked body LMas and the bonding layer Bi are formed. The diameter of each memory hole is enlarged in the bonding layer Bi, and each memory hole is filled with a sacrificial layer, such as an amorphous silicon layer or the like. As a result, the pillar LPLs each including a bonding portion Bps at the upper end are formed.

As illustrated in FIGS. 6B and 6C, in parallel with the above, pillars LHSTs, in which the lower layer structures of the pillars HST are each filled with a sacrificial layer and each includes a bonding portion Bts at the upper end, are formed in the stacked body LMas. In addition, columnar portions LHRs, in which the lower layer structures of the columnar portions HR are each filled with a sacrificial layer and each includes a bonding portion Brs, are formed in the stacked body LMas.

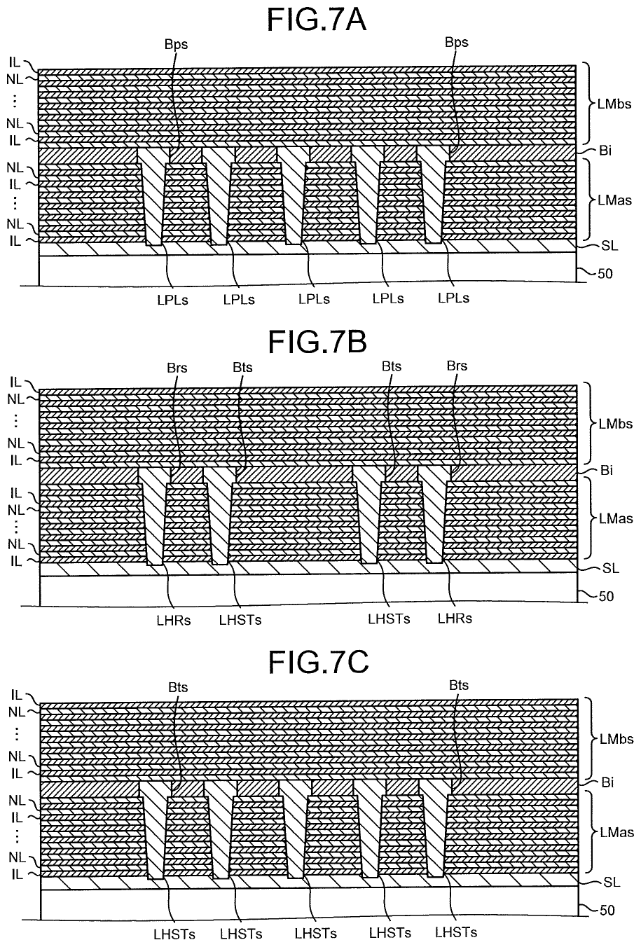

As illustrated in FIGS. 7A to 7C, a stacked body LMbs, in which insulating layers NL and insulating layers IL are alternately stacked in multiple layers, is formed on the stacked body LMas via the bonding layer Bi.

Although not illustrated in FIGS. 7A to 7C, a step-like structure is formed at each end of the stacked body LMbs at this timing.

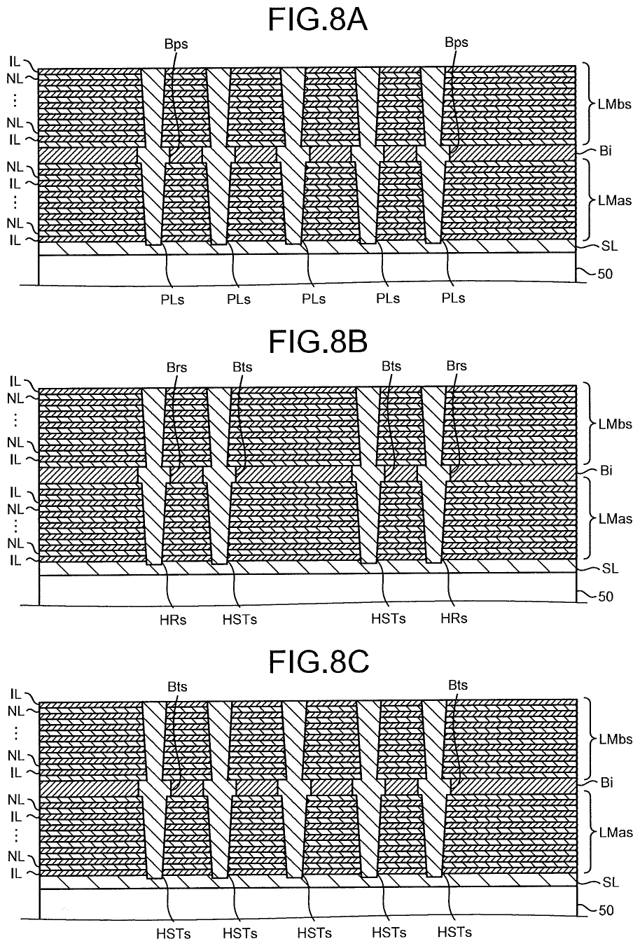

As illustrated in FIG. 8A, pillars PLs, in which the upper and lower layer structures of the pillars PL are each filled with a sacrificial layer, are formed. That is, memory holes that penetrate the stacked body LMbs and are connected to the bonding portions Bps of the pillars LPLs, are formed, and each memory hole is filled with a sacrificial layer, such as an amorphous silicon layer or the like. As a result, the pillars PLs each including the bonding portion Bps near the center are formed.

As illustrated in FIG. 8B and FIG. 8C, in parallel with the above, pillar HSTs, in which the upper and lower layer structures of the pillars HST are each filled with a sacrifice layer and each includes the bonding portion Bts near the center, are formed. In addition, columnar portions HRs, in which the upper and lower structures of the columnar portions HR are each filled with a sacrificial layer and each includes the bonding portion Brs near the center, are formed.

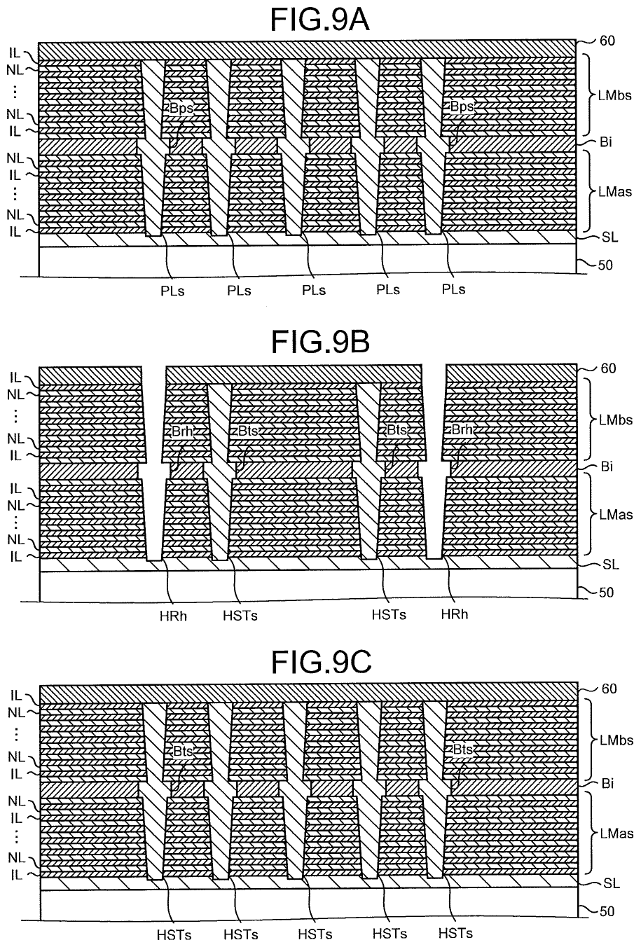

As illustrated in FIGS. 9A to 9C, a mask pattern 60, such as a resist pattern or the like, is formed on the stacked body LMbs including the pillars PLs and HSTs. As a result, only the tops of the columnar portions HRs are opened.

As illustrated in FIG. 9B, the sacrificial layers of the columnar portions HRs are removed from the openings of the mask pattern 60 with an aqueous choline solution (TMY) or the like. As a result, holes HRh whose upper and lower sides communicate with each other via bonding portions Brh near the center are formed.

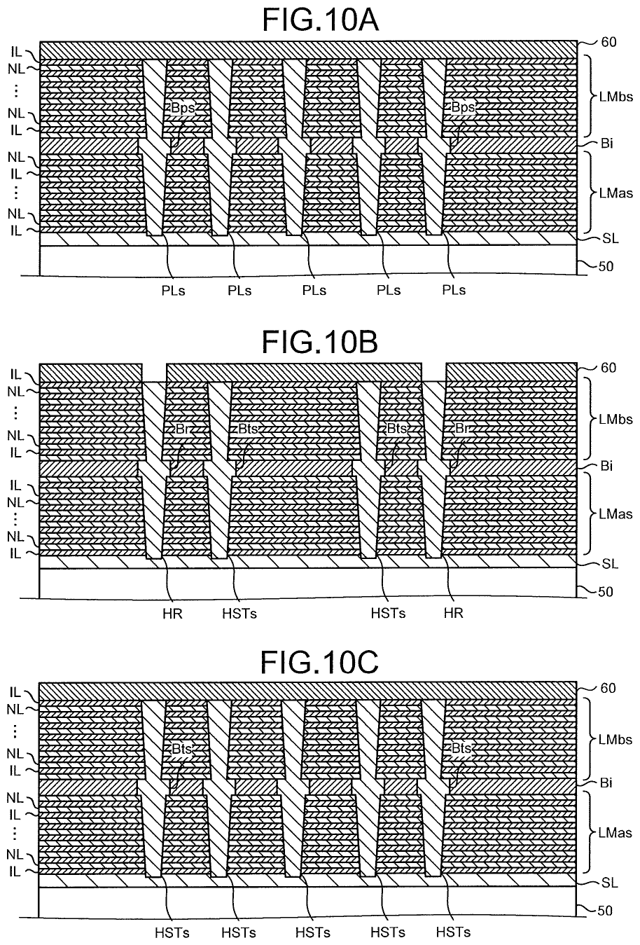

As illustrated in FIG. 10B, the holes HRh are filled from the openings of the mask pattern 60 with an insulating layer, such as a SiO₂ layer or the like, to form the columnar portions HR.

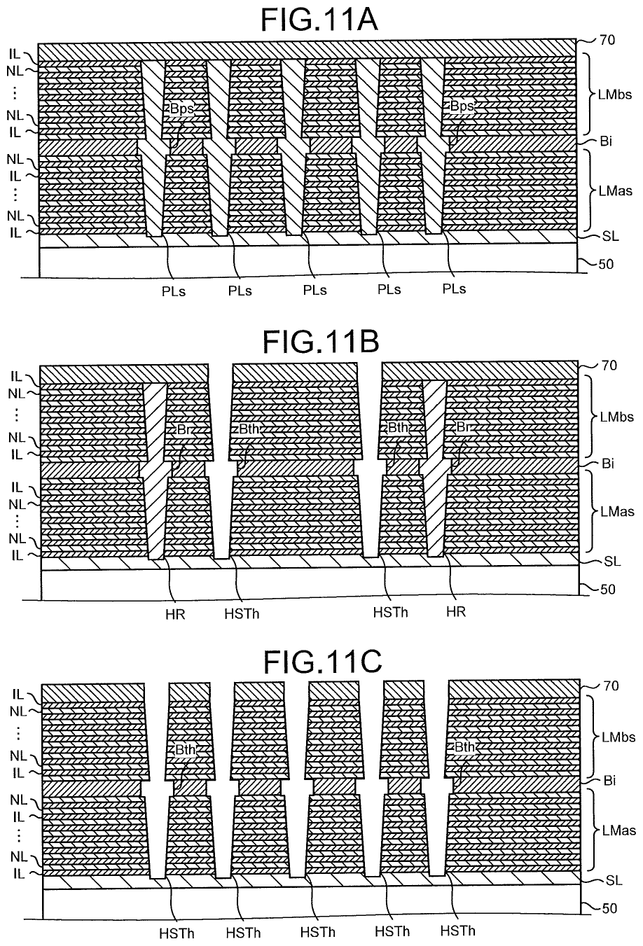

As illustrated in FIGS. 11A to 11C, a mask pattern 70, such as a SiN pattern or the like, is formed on the stacked body LMbs including the pillars PLs and the columnar portions HR. As a result, only the tops of the pillars HSTs are opened.

As illustrated in FIGS. 11B and 11C, the sacrifice layers of the pillars HSTs are removed from the openings of the mask pattern 70 with a choline aqueous solution or the like. As a result, holes HSTh whose upper and lower sides communicate with each other via bonding portions Bth near the center are formed.

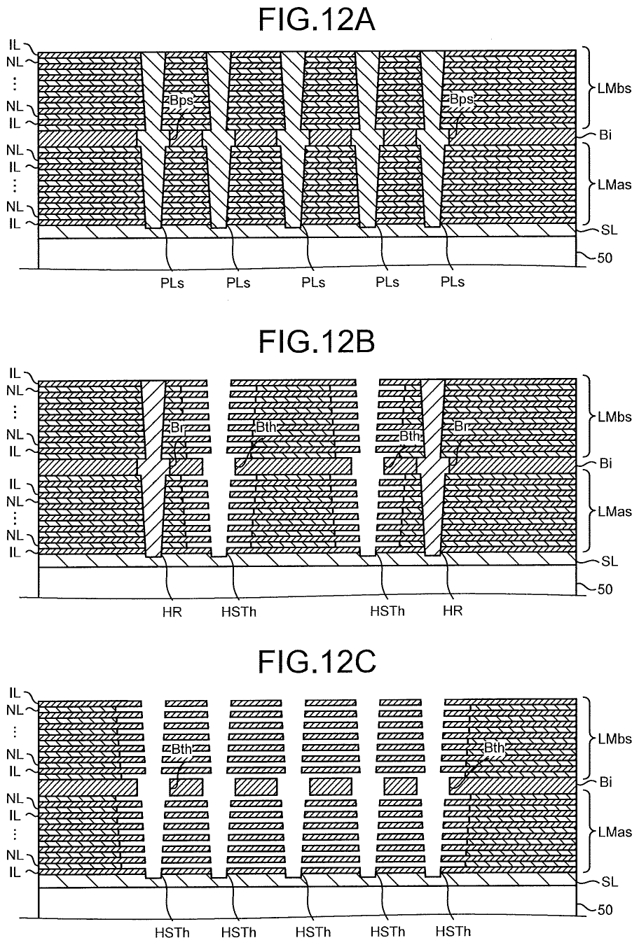

As illustrated in FIGS. 12B and 12C, each insulating layer NL exposed on the inner walls of the holes HSTh is receded by isotropic etching with heat phosphoric acid (H₃PO₄) or the like from the openings of the mask pattern 70. Each insulating layer NL is receded substantially concentrically with respect to the inner walls of the holes HSTh. With the processing for a predetermined time, all the insulating layers NL between the holes HSTh adjacent in the X direction are removed.

As illustrated in FIGS. 12A to 12C, the mask pattern 70 on the stacked body LMbs is also removed substantially at the same time.

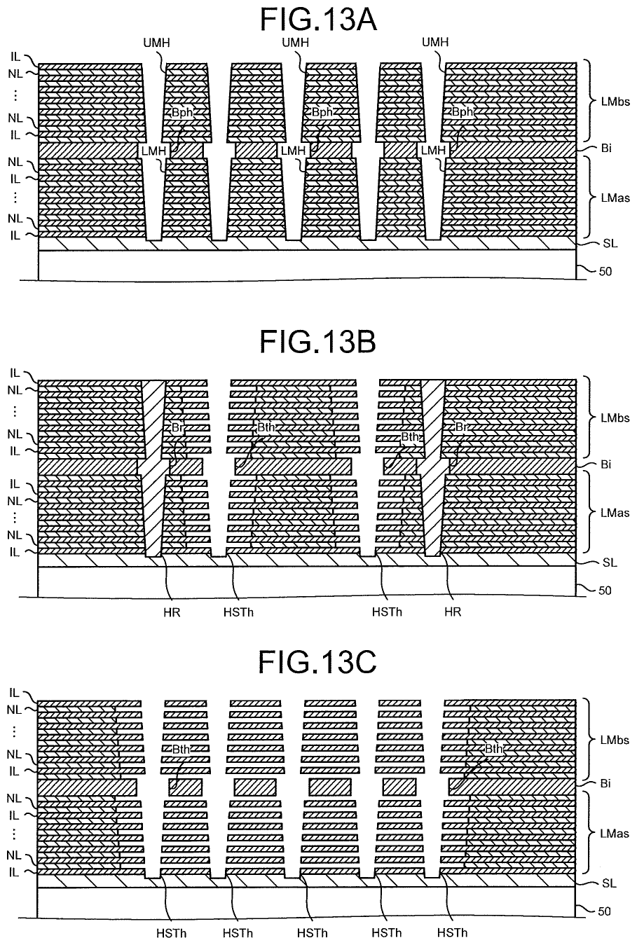

As illustrated in FIG. 13A, the sacrificial layers of pillars PLs are removed with an aqueous choline solution or the like. As a result, memory holes UMH in upper layers and memory holes LMH in lower layers communicate with each other via bonding portions Bph near the center.

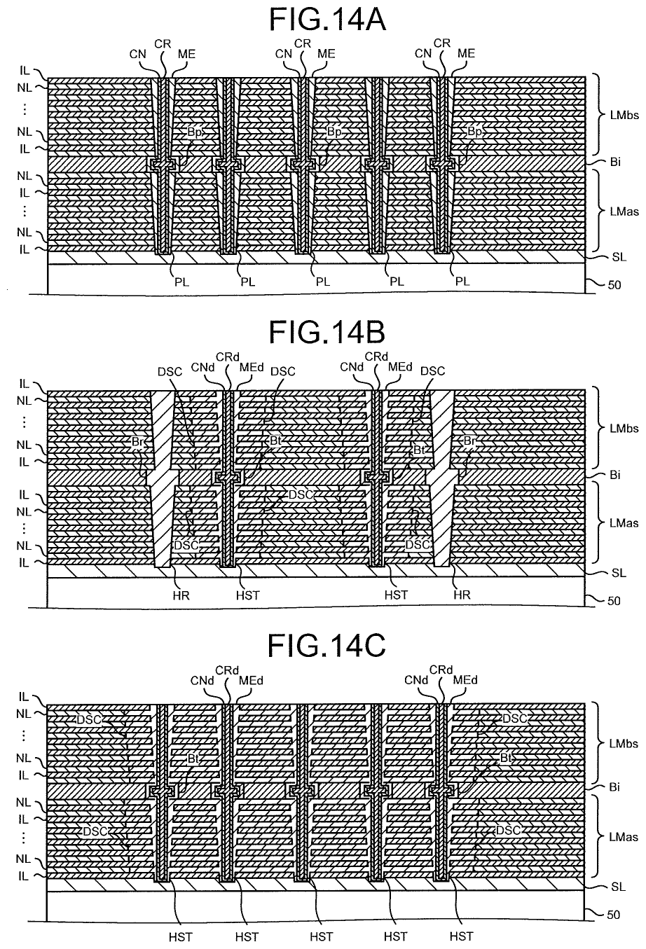

As illustrated in FIG. 14A, pillars PL are formed in the stacked bodies LMas and LMbs. That is, a memory layer ME, such as a SiO₂ layer/SiN layer/SiO₂ layer or the like, a channel layer CN, such as an amorphous silicon layer, a polysilicon layer, or the like, and a core layer CR, such as a SiO₂ layer or the like, are formed in this order from the inner wall side of the respective memory holes LMH and UMH and the bonding portion Bph. The channel layer CN is also formed at the bottom of the memory hole LMH. As a result, the pillars PL each including the bonding portion Bp near the center is formed.

As illustrated in FIGS. 14B and 14C, in parallel with the above, pillars HST are formed in the stacked bodies LMas and LMbs. That is, a dummy layer MEd, such as a SiO₂ layer/SiN layer/SiO₂ layer or the like, a dummy layer CNd, such as an amorphous silicon layer, a polysilicon layer, or the like, and a dummy layer CRd, such as a SiO₂ layer or the like, are formed in this order from the inner wall side of each hole HSTh and the bonding portion Bth. The dummy layer CNd is also formed at the bottom of the hole HSTh. The dummy layer MEd may also be formed at the bottom of the hole HSTh.

Here, a condition with good step coverage is used for embedding into the pillars PL and HST. For this reason, when the dummy layer MEd is embedded in the hole HSTh, the gap formed by receding the insulating layers NL with heat phosphoric acid is also filled with a part of the dummy layer MEd. That is, the outermost SiO₂ layer of the dummy layer MEd is formed on the lower surfaces of the insulating layers IL on the upper layer side and on the upper surfaces of the insulating layers IL on the lower layer side in the gap. The SiO₂ layer on the upper and lower surfaces grows further, and the entire gap is filled with the SiO₂ layer.

With the above, the pillars HST including the plate-like portions DSC protruding at the height positions of the insulating layers NL are formed.

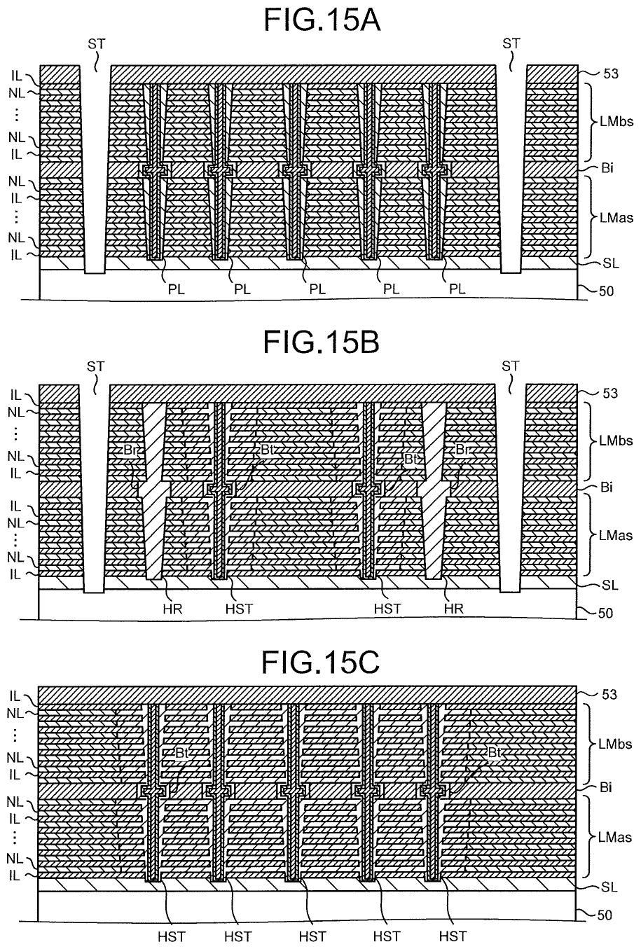

As illustrated in FIGS. 15A to 15C, the insulating layer 53 is formed on the stacked body LMbs.

As illustrated in FIGS. 15A and 15B, slits ST that penetrates the insulating layer 53, the stacked body LMbs, the bonding layer Bi, and the stacked body LMas, and reaches the source line SL are formed.

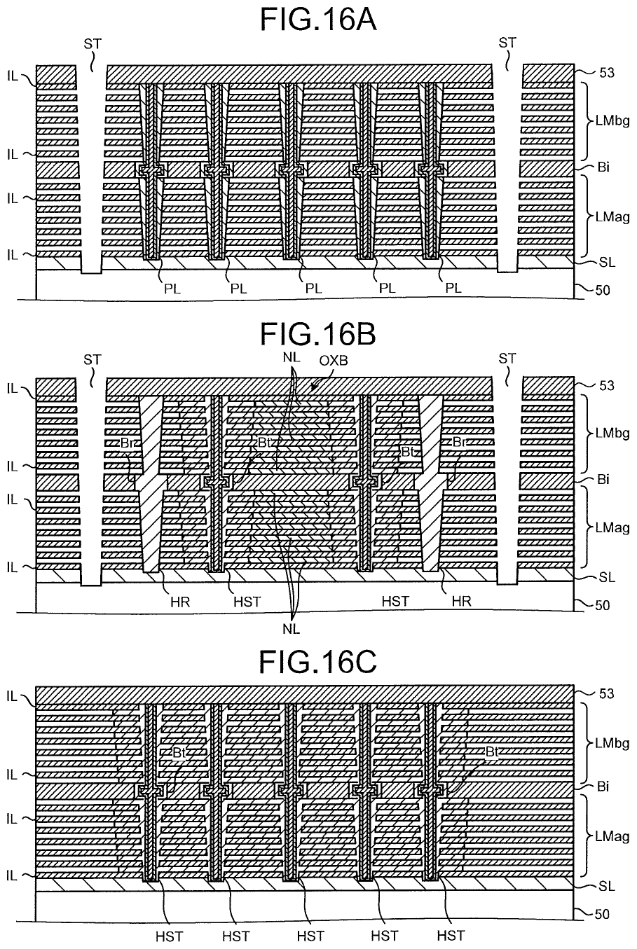

As illustrated in FIGS. 16A to 16C, the insulating layers NL in the stacked bodies LMas and LMbs are removed by heat phosphoric acid or the like through the slits ST penetrating the stacked bodies LMas and LMbs. As a result, stacked bodies LMag and LMbg, in which gaps are formed between the insulating layers IL, are formed.

At this time, the columnar portions HR extending in the stacking direction of the stacked bodies LMag and LMbg and reaching the source line SL support the stacked bodies LMag and LMbg having the gaps. In addition, the pillars HST connected to each other by the plate-like portions DSC may also function as the support columns of the stacked bodies LMag and LMbg.

As illustrated in FIG. 16B, in the region between the pillars HST arranged in the X direction, heat phosphoric acid is prevented from entering from the Y direction by the pillars HST and the plate-like portions DSC protruding from the side surfaces of the pillars HST. The processing is finished before the heat phosphoric acid infiltrates from the X direction. As a result, the through contact region OXB, in which the insulating layers NL are remained without being removed, is formed.

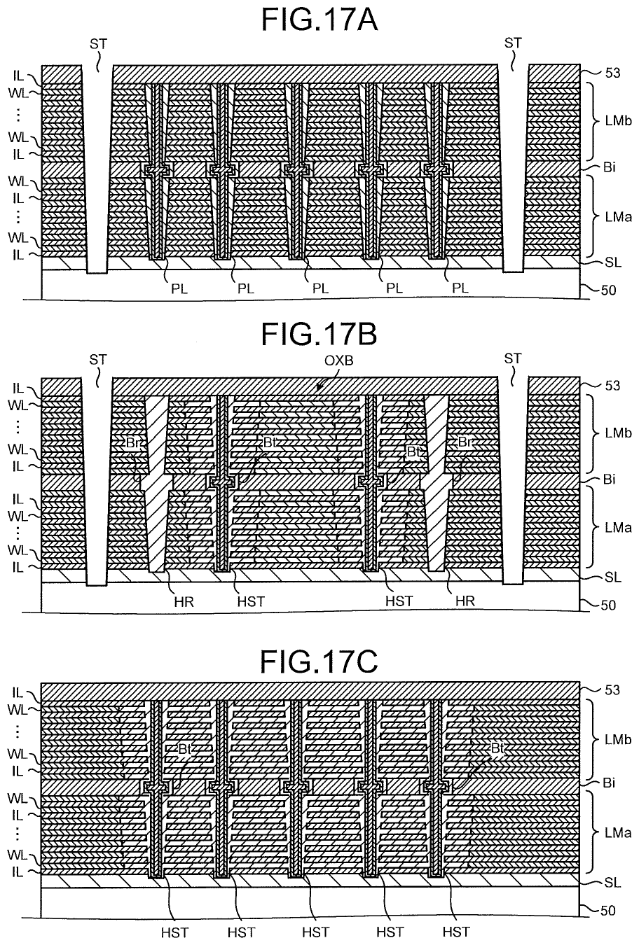

As illustrated in FIGS. 17A to 17C, the gaps in the stacked bodies LMag and LMbg are filled with a conductive material through the slits ST penetrating the stacked bodies LMag and LMbg. As a result, the stacked bodies LMa and LMb, in which the word lines WL are formed between the insulating layers IL, are formed.

The processing for replacing the sacrificial layers, such as the insulating layers NL or the like, with the word lines WL as illustrated in FIGS. 16A to 17C can be referred to as replacement.

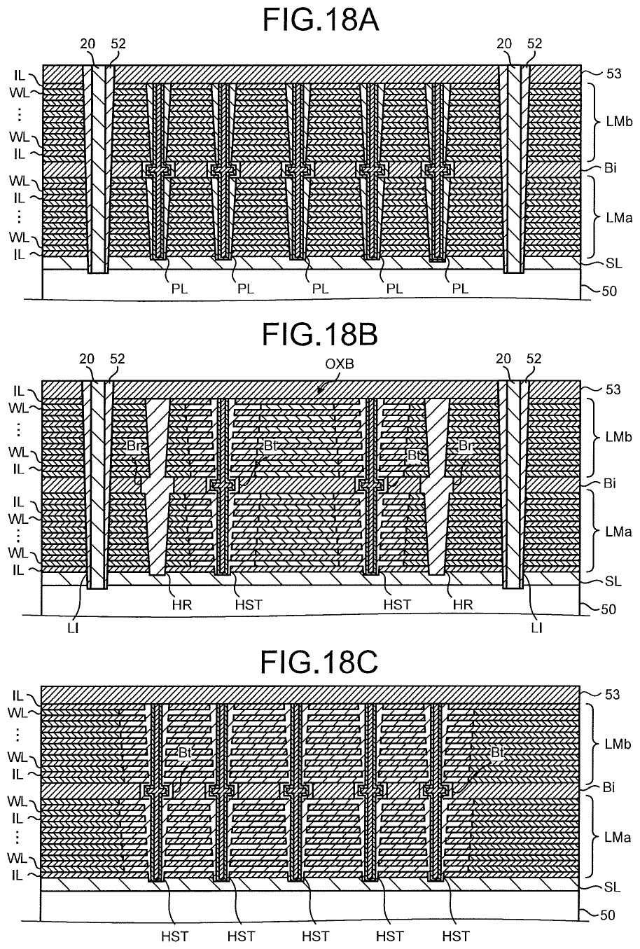

As illustrated in FIGS. 18A and 18B, the insulating layer 52 is formed on the inner wall of each slit ST. The inside the insulating layer 52 is further filled with the conductive layer 20. As a result, the contacts LI connected to the source line SL are formed.

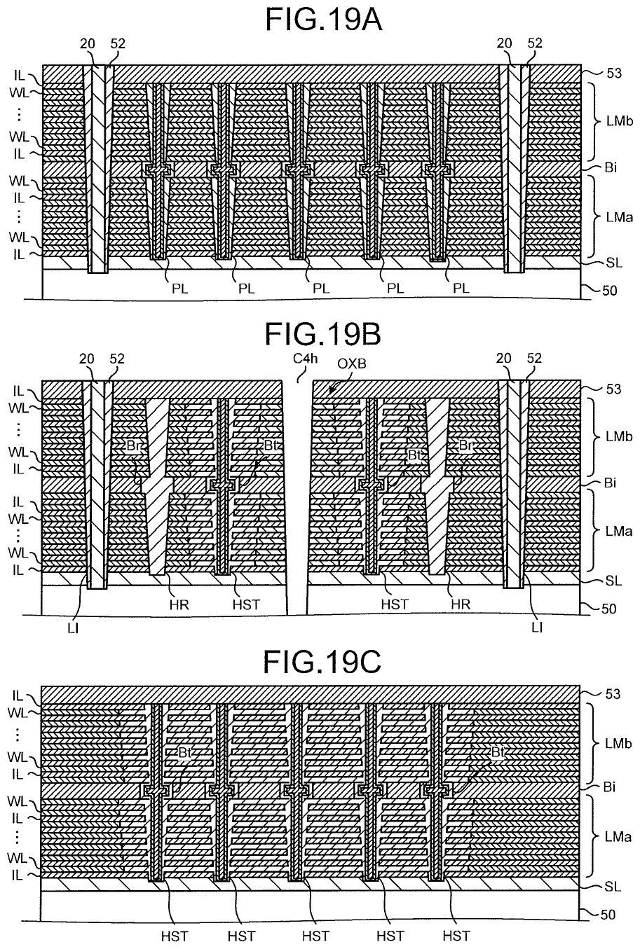

As illustrated in FIG. 19B, holes C4h that penetrate the insulating layer 53, the through contact region OXB, and the source line SL, and reach the wiring and the like of the peripheral circuit CUA are formed.

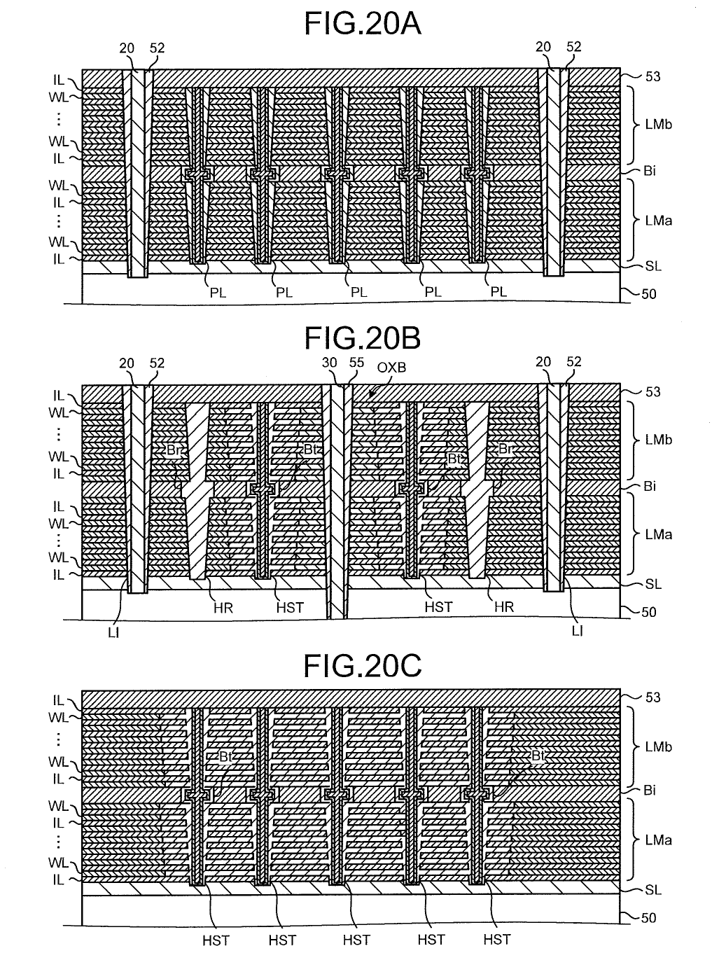

As illustrated in FIG. 20B, the insulating layer 55 is formed on the inner wall of each hole C4h. The inside the insulating layer 55 is further filled with the conductive layer 30. As a result, the contacts C4 connected to the wiring and the like of the peripheral circuit CUA are formed.

Although not illustrated in FIG. 20B, at this timing, the contact CC (see FIG. 1) connected to the word line WL is formed at each step of the step-like structure at the ends of the stacked bodies LMa and LMb.

Then, the insulating layer 54 is formed on the insulating layer 53. A plug CH that penetrates the insulating layers 54 and 53 and is connected to the channel layer CN of each pillar PL is formed. A plug VO that penetrates the insulating layer 54 and is connected to the respective contacts LI and C4 is formed. Furthermore, the upper layer wiring thereof is formed.

With the above, the semiconductor memory device 1 according to the embodiment is manufactured.

In a process for manufacturing a semiconductor memory device, such as a three-dimensional nonvolatile memory, after a stacked body formed by stacking a plurality of insulating layers via a different insulating layer is processed to form pillars, the insulating layers are replaced with word lines. At this time, in order to pass a contact that connects the upper structure and the lower structure of the stacked body, the insulating layers may be left in a partial region of the stacked body. For this purpose, a configuration for inhibiting the replacement in the partial region is provided.

As a configuration for inhibiting the replacement, for example, when forming a slit for replacement, a slit parallel to this slit may be formed in the stacked body, and an SiO₂ layer or the like may be formed on the inner wall of the slit to function as a slit for inhibiting replacement. However, it is required to form a slit for replacement without an SiO₂ layer or the like on the inner wall and a slit for inhibiting replacement with an SiO₂ layer or the like on the inner wall in parallel, and which can cause a large dimensional conversion difference between these slits.

According to the semiconductor memory device 1 in the embodiment, the pillars HST formed in parallel with the pillars PL are provided as a configuration for inhibiting replacement. Thus, it is possible to inhibit replacement in the through contact region OXB while the dimensional conversion difference of the slits ST is reduced.

According to the semiconductor memory device 1 in the embodiment, the plate-like portions DSC included in the pillars HST are embedded in parallel with the process for embedding the memory layers ME of the pillars PL. Thus, it is possible to embed the plate-like portions DSC under a condition with good step coverage, and to more reliably inhibit the replacement in the through contact region OXB.

According to the semiconductor memory device 1 in the embodiment, the pillars HST each have a lower end connected to the source line SL and are connected to each other by the plate-like portions DSC. Thus, it is possible for the pillars HST, in addition to the columnar portions HR, to support the stacked bodies LMag and LMbg in the replacement.

In the above embodiment, the diameter and pitch of the pillars HST at the height position of each insulating layer IL have been substantially equal to the diameter and pitch of the pillars PL. In addition, the plate-like portions DSC have protruded from the pillars HST, and the adjacent pillars HST have been connected to each other by the plate-like portions DSC. However, the diameter of each pillar HST at the height position of each insulating layer IL may be increased, and the protrusion amount of the plate-like portion DSC from each pillar HST may be reduced accordingly. Alternatively, the diameter of each pillar HST may be reduced, and the protrusion amount of the plate-like portion DSC from each pillar HST may be increased accordingly. Similarly, the pitch of the pillars HST may not be equal to the pitch of the pillars PL.

### Modified Example 1

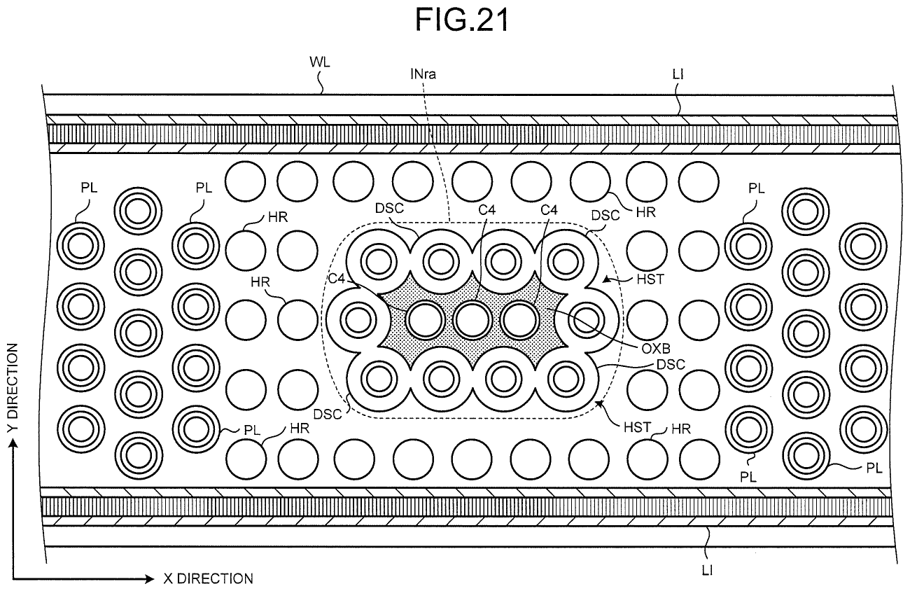

Next, a semiconductor memory device in Modified example 1 of the embodiment is described with reference to FIG. 21. The semiconductor memory device in Modified example 1 is different from the above embodiment in that a replacement inhibition portion INra surrounds the through contact region OXB.

As illustrated in FIG. 21, the pillars HST constituting the replacement inhibition portion INra are arranged not only in the X direction but also in the Y direction, and the pillars HST connected to each other by the plate-like portions DSC surround the through contact region OXB.

According to the semiconductor memory device in Modified example 1, the replacement inhibition portion INra surrounds the through contact region OXB. Thus, it is possible to prevent heat phosphoric acid from infiltrating from the X direction, and to more reliably inhibit the replacement in the through contact region OXB.

According to the semiconductor memory device in Modified example 1, the pillars HST arranged in the Y direction prevent heat phosphoric acid from infiltrating from the X direction. Thus, it is possible to shorten the arrangement of the pillars HST in the X direction by omitting the arrangement in the X direction of the excessive pillars HST for diverting the infiltration of the heat phosphoric acid in the through contact region OXB. Therefore, it is possible to reduce the region surrounded by the replacement inhibition portion INra.

According to the semiconductor memory device in Modified example 1, the replacement inhibition portion INra is constituted by a plurality of pillars HST. Thus, by variously changing the arrangement of the pillars HST, it is possible to form the replacement inhibition portion INra in a desired shape.

### Modified Example 2

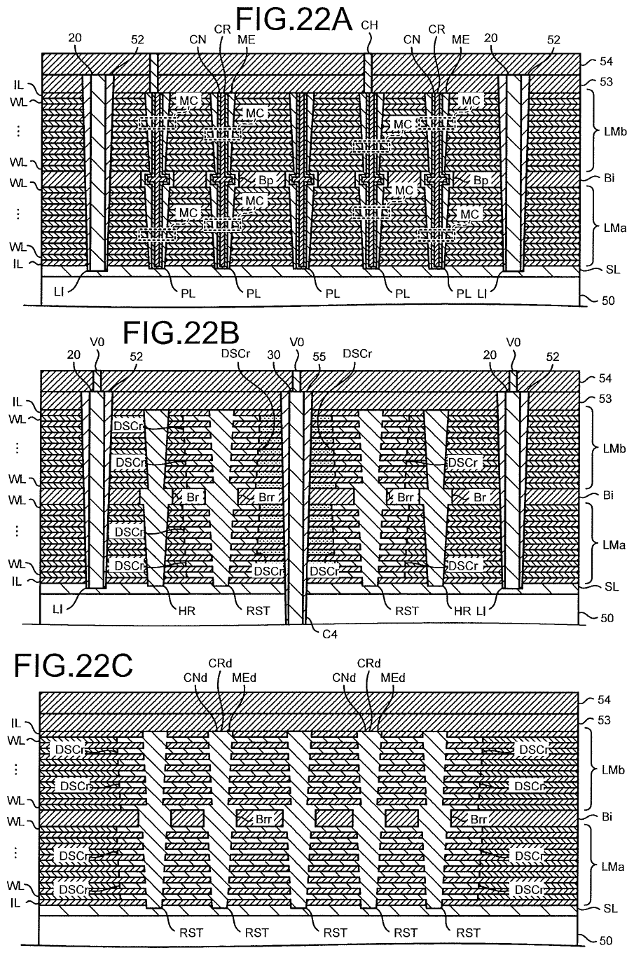

Next, a semiconductor memory device in Modified example 2 of the embodiment is described with reference to FIGS. 22A to 22C. The semiconductor memory device in Modified example 2 is different from the above embodiment in that columnar portions RST formed in parallel with the columnar portions HR are included as a configuration for inhibiting replacement.

As illustrated in FIGS. 22A to 22C, the semiconductor memory device in Modified example 2 includes columnar portions RST as second pillars. The columnar portions RST are arranged in the X direction on both sides of the through contact region OXB in the Y direction. As a result, a replacement inhibition portion is constituted. The replacement inhibition portion surrounding the through contact region OXB may be configured by arranging the columnar portions RST in the Y direction.

Each columnar portion RST penetrates the boundary between the stacked bodies LMa and LMb and the through contact region OXB in the stacking direction of the stacked bodies LMa and LMb and reaches the source line SL. Each columnar portion RST includes a bonding portion Brr in the bonding layer Bi. Each columnar portion RST is filled with an insulating layer made of the same material as the columnar portions HR, such as a SiO₂ layer or the like.

The diameter and pitch of the columnar portions RST at the height position of each insulating layer IL are substantially equal to the diameter and pitch of the columnar portions HR, for example. However, the diameter of the columnar portions RST may not be equal to the diameter of the columnar portions HR as long as the adjacent columnar portions RST are connected to each other by plate-like portions DSCr to be described later. Similarly, the pitch of the columnar portions RST may not be equal to the pitch of the columnar portions HR.

A plurality of flat plate-like portions DSCr protrudes from the side surface of each columnar portion RST at the height positions of the word lines WL. Each plate-like portion DSCr is constituted by a part of the insulating layer with which the columnar portions RST are filled, and has a shape formed by, for example, overlapping the end portion of a disk-like member extending concentrically with the side surface of each columnar portion RST with the end portions of the adjacent columnar portions RST in a top view.

As a result, the adjacent columnar portions RST are connected to each other at the end portions of the plate-like portions DSCr at the same height position of the columnar portions RST. In addition, the insulating layers IL are continuously disposed in the through contact region OXB and the stacked bodies LMa and LMb on both sides of the through contact region OXB through the adjacent columnar portions RST.

Such the columnar portions RST are formed in parallel with the columnar portions HR. That is, the diameters of holes formed in parallel with the holes HRh for forming the columnar portions HR are expanded at the insulating layers NL to form the columnar portions RST having the plate-like portions DSCr.

In the above embodiment and Modified examples 1 and 2, the semiconductor memory device has included the stacked bodies LMa and LMb configured in two tiers, but is not limited thereto. The semiconductor memory device may include only one-tiered stacked body or three-or-more tiered stacked body.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a plurality of belt-like portions arranged abreast to each other above the substrate and extending in a first direction along the substrate;
a first stacked body disposed between the belt-like portions and stacked a plurality of first conductive layers via a first insulating layer;
a second stacked body disposed in a region in the first stacked body and stacked a plurality of second insulating layers via the first insulating layer;
a first pillar extending in the first stacked body in a stacking direction of the first stacked body and forming a memory cell at an intersection with at least a part of the first conductive layers; and
a plurality of second pillars extending in the stacking direction on both sides of the second stacked body facing the belt-like portions and arranged in the first direction, wherein
the second pillars each include a plate-like portion disposed at a height position of each of the first conductive layers, and
the adjacent second pillars are connected to each other by the plate-like portion.

2. The semiconductor memory device according to claim 1, wherein
the first pillar is one of a plurality of first pillars,
the first stacked body includes a memory region in which the first pillars are disposed, and
the second stacked body is disposed in the memory region.

3. The semiconductor memory device according to claim 1, wherein a contact extending in the stacking direction is disposed in a region in the second stacked body.

4. The semiconductor memory device according to claim 3, further comprising
a second conductive layer disposed below the first conductive layers, wherein
the first pillar has a lower end connected to the second conductive layer, and
the contact penetrates the second conductive layer and has a lower end connected to lower wiring disposed between the substrate and the second conductive layer.

5. The semiconductor memory device according to claim 1, wherein
the second pillars are also arranged in a second direction intersecting the first direction, and
the second stacked body is surrounded by the second pillars.

6. The semiconductor memory device according to claim 1, wherein
the first pillar includes a memory layer disposed on an outer periphery of the first pillar, and
the plate-like portion is made of a same material as at least a part of the memory layer.

7. The semiconductor memory device according to claim 6, wherein
the first pillar is one of a plurality of first pillars, and
a pitch of the first pillars and a pitch of the second pillars are substantially equal.

8. The semiconductor memory device according to claim 6, wherein
a diameter of the first pillar and a diameter of each of the second pillars are substantially equal at a height position of the first insulating layer.

9. The semiconductor memory device according to claim 1, further comprising
a columnar portion extending in the first stacked body in the stacking direction of the first stacked body and filled with a third insulating layer, wherein
the plate-like portion is made of a same material as the third insulating layer.

10. The semiconductor memory device according to claim 9, wherein
the columnar portion is one of a plurality of columnar portions, and
a pitch of the columnar portions and a pitch of the second pillars are substantially equal.

11. The semiconductor memory device according to claim 9, wherein
a diameter of the columnar portion and a diameter of each of the second pillars are substantially equal at a height position of the first insulating layer.

12. The semiconductor memory device according to claim 1, wherein the plate-like portion extends concentrically from a side surface of each of the second pillars, except for portions connected to each other.

13. The semiconductor memory device according to claim 1, wherein the first insulating layer is continuously formed over a region in the second stacked body and a region of the first stacked body on both sides of the second stacked body through the adjacent second pillars.

14. The semiconductor memory device according to claim 1, wherein each of the first conductive layers in the first stacked body has an edge facing the second pillars and having a shape formed by connecting a plurality of arcs.

15. A method for manufacturing a semiconductor memory device,
the semiconductor memory device comprising:
a first stacked body stacked a plurality of conductive layers via a first insulating layer above a substrate;
a second stacked body disposed in a region in the first stacked body and stacked a plurality of second insulating layers via the first insulating layer; and
a first pillar extending in the first stacked body in a stacking direction of the first stacked body and forming a memory cell at an intersection with at least a part of the conductive layers, and
the method comprising:
forming a plurality of first through holes extending in a boundary portion between a first region and a second region of a third stacked body in the stacking direction and arranged in two rows in a first direction along the substrate, the third stacked body being stacked the second insulating layers via the first insulating layer, and the first stacked body being to be formed in the first region of the third stacked body by replacing the second insulating layers of the first region with the conductive layers and the second stacked body being to be formed in the second region of the third stacked body by inhibiting replacement of the second insulating layers of the second region with the conductive layers;
receding the second insulating layers from inner wall surfaces of the first through holes to remove the second insulating layers between the first through holes adjacent in the same row;
covering the inner wall surfaces of the first through holes with a third insulating layer and filling, with the third insulating layer, a gap from which the second insulating layers have been removed to form a plurality of second pillars connected to each other in the same row by the third insulating layer;
forming, outside an arrangement of the second pillars in two rows, a groove extending in the third stacked body in the stacking direction and facing the arrangement of the second pillars; and
replacing, with the conductive layers, the second insulating layers between the second pillars and the groove without replacing the second insulating layers inside the arrangement of the second pillars in two rows.

16. The method for manufacturing the semiconductor memory device according to claim 15, further comprising forming a contact extending in a region in the second stacked body in the stacking direction.

17. The method for manufacturing the semiconductor memory device according to claim 15, further comprising:
arranging the second pillars in a second direction intersecting the first direction, the second stacked body being formed in a region surrounded by the second pillars.

18. The method for manufacturing the semiconductor memory device according to claim 15, further comprising:
forming a second through hole extending in the third stacked body in the stacking direction and covering an inner wall surface of the second through hole with a memory layer and covering the memory layer with a channel layer to form the first pillar in the first region, wherein
the inner wall surfaces of the first through holes are covered with the third insulating layer made of a same material as at least a part of the memory layer in parallel with covering the inner wall surface of the second through hole with the memory layer.

19. The method for manufacturing the semiconductor memory device according to claim 15, further comprising:
forming a third through hole extending in the third stacked body in the stacking direction and filling the third through hole with the third insulating layer to form a columnar portion in the first region, wherein
the inner wall surfaces of the first through holes are covered with the third insulating layer in parallel with filling the third through hole with the third insulating layer.

20. The method for manufacturing the semiconductor memory device according to claim 15, wherein,
the second insulating layers are concentrically receded from the inner wall surfaces of the first through holes by isotropic etching the second insulating layers between the first through holes adjacent in the same row.
